(19) United States
(12) Patent Application Publication
(10) Pub. No.: US 2023/0201848 A1
(43) Pub. Date: Jun. 29, 2023

(54) SPRAY PUMP

(71) Applicant: PROTEC CO., LTD., Gyeonggi-do (KR)

(72) Inventors: Seung Min HONG, Seoul (KR); EUI KEUN CHOI, Seoul (KR); Sung Il PARK, Gyeonggi-do (KR); Keon Hee KIM, Incheon (KR)

(73) Assignee: PROTEC CO., LTD., Gyeonggi-do (KR)

(21) Appl. No.: 17/950,103

(22) Filed: Sep. 22, 2022

(30) Foreign Application Priority Data
Dec. 29, 2021 (KR) 10-2021-0191187

(51) Int. Cl. B05B 1/30; B05B 7/24

(52) U.S. Cl. CPC B05B 1/304; B05B 7/2489

(57) ABSTRACT

A spray pump formed to atomize and apply a viscous liquid may micro-discharge the viscous liquid ranging from low to high viscosity in a quantitative manner, may miniaturize a device capable of atomizing liquids by spraying, and may shorten a spraying path to prevent changes in liquid properties and keep spraying quality constant.

### CROSS-REFERENCE TO RELATED APPLICATION

This application is based on and claims priority under 35 U.S.C. § 119 to Korean Patent Application No. 10-2021-0191187, filed on Dec. 29, 2021, in the Korean Intellectual Property Office, the disclosure of which is incorporated by reference herein in its entirety.

### BACKGROUND

### 1. Field

The present disclosure relates to a spray pump, and more particularly, to a spray pump capable of spraying and applying a viscous liquid.

### 2. Description of the Related Art

As the scope of application of semiconductors such as electronic products and devices, automobile industries, and military industries has been expanded, the demand for semiconductors is gradually increasing. In the case of a semiconductor package, an electromagnetic wave shielding film is generally formed in order to prevent electromagnetic wave emission or damage to an internal circuit due to external electromagnetic waves and to ensure stable operation of devices.

As electronic products are manufactured in a thin and small form, the demand for packaging is rapidly increasing. Electromagnetic wave shielding has a greater impact on systems or components that are smaller than wavelength. With classical shielding methods, it is difficult to shield electromagnetic waves of miniaturized and lightweight electronic products.

A sputtering (deposition) process is sometimes used as a method of forming electromagnetic wave shielding films. In the case of the method using the sputtering process, the process is complicated, and it takes a lot of time and money. In addition, there are inconveniences in the process such as masking where electromagnetic wave shielding is not required. In addition, elements inside the semiconductor package may be damaged by heat generated during the sputtering process.

Accordingly, a method of forming electromagnetic wave shielding films by applying a viscous liquid to semiconductor chips or semiconductor package using a pump capable of applying the viscous liquid without using a deposition method has been attempted. If the viscous liquid may be applied with a fine line width and accurate capacity at a correct position by using the pump that applies the viscous liquid, the productivity of the process of forming the shielding film may be improved.

### SUMMARY

An object of the present disclosure is to provide a spray pump that may precisely apply a viscous liquid with a fine line width by spraying the viscous liquid.

Additional aspects will be set forth in part in the description which follows and, in part, will be apparent from the description, or may be learned by practice of the presented embodiments of the disclosure.

A spray pump in the present disclosure includes a syringe in which a viscous liquid is stored; a valve member including a reservoir receiving the viscous liquid from the syringe and storing the same, a nozzle connected to a lower portion of the reservoir to discharge the viscous liquid to an outside, and a sheath passage extending toward an end of the nozzle to eject a gas to spray the viscous liquid discharged from the nozzle; a valve rod inserted into the reservoir of the valve member so as to move forward and backward with respect to the nozzle of the valve member and discharge the viscous liquid stored in the reservoir through the nozzle; and an operation member moving the valve rod back and forth with respect to the valve member.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a spray pump according to one embodiment of the present disclosure;

FIG. 2 is an enlarged view of part A of the spray pump illustrated in FIG. 1;

FIG. 3 is a bottom view of a portion of the spray pump illustrated in FIG. 1; and

FIG. 4 is bottom view of a portion of the spray pump according to another embodiment of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the accompanying drawings, a spray pump according to an embodiment of the present disclosure will be described.

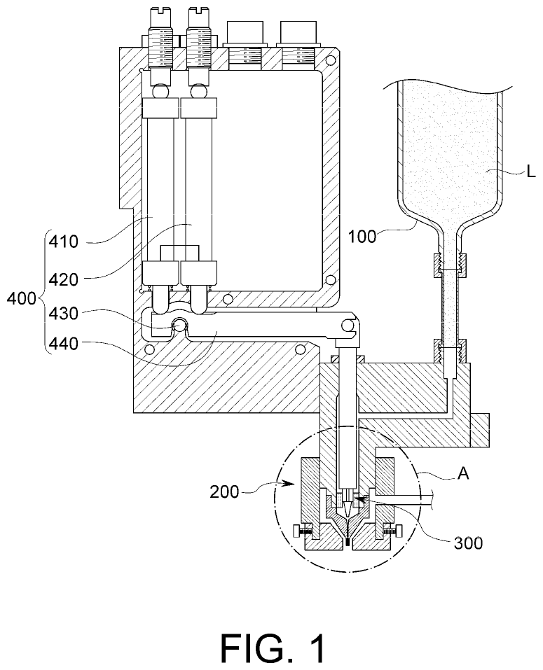

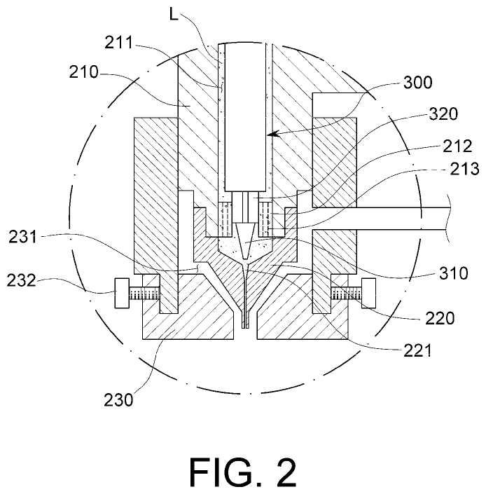

FIG. 1 is a cross-sectional view of a spray pump according to one embodiment of the present disclosure, and FIG. 2 is an enlarged view of part A of the spray pump illustrated in FIG. 1.

Referring to FIGS. 1 and 2, a spray pump of an embodiment of the present disclosure includes a syringe 100, a valve member 200, a valve rod 300 and an operation member 400. The spray pump of this embodiment is a device for discharging a viscous liquid L and spraying the discharged viscous liquid L for application. Here, the viscous liquid L is a generic term for an insulating and non-insulating resin having a viscosity, such as a highly viscous conductive liquid for forming an electromagnetic wave shielding film of a semiconductor chip package.

The syringe 100 is formed in a shape of a container so that the viscous liquid L may be stored.

The valve member 200 includes a reservoir 211, a nozzle 221 and a sheath passage 231. The reservoir 211 stores the viscous liquid L supplied from the syringe 100. The nozzle 221 is connected to a lower portion of the reservoir 211 so as to discharge the viscous liquid L stored in the reservoir 211 to an outside. The sheath passage 231 is formed to extend toward an end of the nozzle 221. A pressurized gas is discharged through sheath passage 231 to spray the viscous liquid L discharged from the nozzle 221.

In this embodiment, the valve member 200 includes a valve body 210, a nozzle member 220 and a nozzle cover member 230.

The reservoir 211 of the valve member 200 is formed on the valve body 210. The reservoir 211 is a space in which the viscous liquid L supplied from the syringe 100 is stored. In the case of this embodiment, the reservoir 211 is formed so that a circular cross-section inside the valve body 210 extends in a longitudinal direction.

The nozzle member 220 is installed in a lower portion of the valve body 210. The nozzle 221 is formed on the nozzle member 220. The nozzle member 220 is formed so that an outer diameter decreases along the extending direction of the nozzle 221. The nozzle 221 is connected to the lower portion of the reservoir 211 to discharge the viscous liquid L of the reservoir 211 to the outside. An inner diameter of the nozzle 221 may be variously changed according to types and uses of the viscous liquid L and processes in which the viscous liquid L is used. The nozzle member 220 may be formed separately from the valve body 210 and then coupled to the valve body 210 as illustrated in FIG. 2, but may also be formed integrally with the valve body 210.

The nozzle cover member 230 is coupled to the nozzle member 220 or the valve body 210 so as to cover a part or all of an outer surface of the nozzle member 220.

The sheath passage 231 is formed to extend through the nozzle cover member 230 between an inner surface of the nozzle cover member 230 and an outer surface of the nozzle member 220. A pipe is connected to the sheath passage 231 to deliver a pressurized air supplied from an outside to the sheath passage 231. The sheath passage 231 between the nozzle cover member 230 and the nozzle member 220 is formed to be closer to the nozzle 221 as it progresses along a direction in which the nozzle 221 extends. That is, a portion of the sheath passage 231 is formed to be inclined with respect to the extending direction of the nozzle 221. To this end, the nozzle cover member 230 is formed such that an inner diameter decreases along the extending direction of the nozzle 221. In addition, it is preferable that an end of the sheath passage 231 is disposed in front (i.e., below) than an end of the nozzle 221.

A position of the nozzle cover member 230 with respect to the valve body 210 is fixed by a fixing bolt 232. After the position of the nozzle cover member 230 with respect to the valve body 210 is adjusted, the position of the nozzle cover member 230 may be fixed by fixing bolt 232. In this way, a gap between the nozzle cover member 230 and the nozzle member 220 may be adjusted. By adjusting the gap between the nozzle cover member 230 and the nozzle member 220, a flow rate of the gas injected through the sheath passage 231 may be adjusted. In some cases, a position where the gas injected from the sheath passage 231 meets the viscous liquid L discharged from the nozzle 221 may also be adjusted. The nozzle cover member 230 may be formed to be screwed to the valve body 210. That is, by tightening or loosening the nozzle cover member 230 with respect to the valve body 210, after a height of the nozzle cover member 230 with respect to the valve body 210 is adjusted, the height may be fixed by the fixing bolt 232. Such the nozzle cover member may be designed and changed in various structures and shapes according to uses and purposes, and may be replaced with a cover member having a different structure as necessary.

The valve rod 300 is formed to extend in a longitudinal direction and is inserted into the reservoir 211 of the valve body 210. The valve rod 300 is moved forward and backward along the extension direction of the reservoir 211 by the operation member 400. In the case of this embodiment, as illustrated in FIGS. 1 and 2, the valve rod 300 is lifted up and down by the operation member 400. As such, when the valve rod 300 repeats forward and backward, the viscous liquid L stored in the reservoir 211 of the valve body 210 is discharged to the outside through the nozzle 221.

In this embodiment, the valve rod 300 includes a needle 310 and a valve guide 320. As illustrated in FIG. 2, the needle 310 is formed at an end of the valve rod 300. The needle 310 of the valve rod 300 faces the nozzle 221. A moment generated by the movement of the valve rod 300 is transferred to the viscous liquid L, so that the viscous liquid L is discharged through the nozzle 221. As an outer diameter of the needle 310 decreases, an amount of the viscous liquid L discharged through the nozzle 221 decreases. As the outer diameter of the needle 310 increases, the amount of viscous liquid L discharged through the nozzle 221 increases.

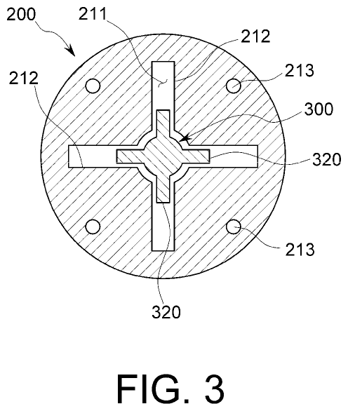

Referring to FIGS. 1 and 2, a reservoir guide 212 and a guide flow passage 213 are formed in the valve body 210. The reservoir guide 212 is formed in the reservoir 211 of the valve body 210. The reservoir guide 212 is formed in a form of a groove formed on an inner wall of the reservoir 211. The reservoir guide 212 extends along a forward/backward direction (vertical direction in the present embodiments) of the valve rod 300. The reservoir guide 212 is disposed in the lower portion of the reservoir 211 adjacent to the nozzle 221 in the valve body 210. A shape of the reservoir guide 212 may be variously modified, but in the present embodiment, as illustrated in FIG. 3, a cross-section is formed in a cross shape (+) and extends vertically. The reservoir guide 212 guides the forward and backward movement of the valve rod 300. The guide flow passage 213 provides a path through which the viscous liquid L stored in the reservoir 211 is smoothly supplied toward the nozzle 221. That is, the guide flow passage 213 of the valve body 210 connects a front space and a rear space of the reservoir guide 212 so that the viscous liquid L flows smoothly between the front space and the rear space of the reservoir guide 212. The front space of the reservoir guide 212 means a portion close to the nozzle 221 of the valve body 210 in the reservoir 211, and the rear space means a portion farther from the nozzle 221 of the valve body 210 in the reservoir 211.

The valve guide 320 of the valve rod 300 is formed at a position corresponding to the reservoir guide 212 of the reservoir 211 in an outer surface of the valve rod 300. The valve guide 320 is disposed behind the needle 310 and is formed to protrude from the outer surface of the valve rod 300. The valve guide 320 is formed in a shape corresponding to the reservoir guide 212 so as to be inserted into the reservoir guide 212. As described above, the cross-section of the reservoir guide 212 is formed in a cross shape (+), and the cross-section of the valve guide 320 is also formed in a cross shape (+) as illustrated in FIG. 3. When the valve rod 300 moves forward and backward within the reservoir 211 of the valve body 210, the valve guide 320 formed on the valve rod 300 is inserted into the reservoir guide 212 and slides forward and backward while linear movement is guided by the reservoir guide 212. An outer diameter of the valve guide 320 is larger than the outer diameter of the needle 310.

The operation member 400 moves the valve rod 300 forward and backward with respect to the valve body 210 as described above. The operation member 400 may be composed of various actuators that may linearly move the valve rod 300. In this embodiment, the operation member 400 is formed as an actuator composed of a piezoelectric element whose length varies according to an applied voltage.

In this embodiment, the operation member 400 is formed of a multi-stack type piezoelectric actuators 410 and 420 in which a plurality of piezoelectric elements are stacked. The piezoelectric actuators 410 and 420 are disposed at positions capable of contacting one end of a lever 440 rotatably installed with respect to a hinge axis 430. An opposite end of the lever 440 is coupled with the valve rod 300. At this time, the hinge axis 430 is disposed close to the piezoelectric actuators 410 and 420. According to operations of the piezoelectric actuators 410 and 420, the lever 440 is rotated, and accordingly, the valve rod 300 is moved forward and backward with respect to the valve body 210. As such, when the operation member 400 moves the valve rod 300 forward and backward quickly, the viscous liquid L is discharged by the needle 310 and the nozzle 221.

Hereinafter, an operation of the spray pump according to an embodiment configured as described above will be described.

The viscous liquid L stored in the syringe 100 is supplied to the reservoir 211. A pneumatic regulator (not illustrated) for pushing the viscous liquid L to the reservoir 211 with a constant pressure is connected to the syringe 100. The viscous liquid L delivered from the syringe 100 is temporarily stored in the reservoir 211.

The operation member 400 rapidly elevates the valve rod 300 inserted into the reservoir 211 to discharge the viscous liquid L stored in the reservoir 211 through the nozzle 221. The operation member 400 for elevating the valve rod 300 may be variously configured, but in this embodiment, the operation member 400 having the structure as illustrated in FIG. 1 is used.

When voltage is applied to the two piezoelectric actuators 410 and 420 constituting the operation member 400, the two piezoelectric actuators 410 and 420 alternately stretch and contract, and the lever 440 rotates clockwise or counterclockwise with respect to the hinge axis 430. According to the rotation of the lever 440, the valve rod 300 moves forward and backward with respect to the valve body 210. When the lever 440 rotates clockwise, the valve rod 300 moves forward, and when the lever 440 rotates counterclockwise, the valve rod 300 moves backward. The hinge axis 430 of lever 440 is located closer to the piezoelectric actuators 410 and 420 than to the valve rod 300. Therefore, an operating displacement of the piezoelectric actuators 410 and 420 is extended and transmitted to the valve rod 300 by the lever 440. For this reason, the valve rod 300 is raised and lowered within a sufficient height range.

The valve member 200 and the valve rod 300 of the spray pump according to this embodiment discharge the viscous liquid L by a method of jetting pump. The operation member 400 moves the valve rod 300 forward and backward at high speed. When the valve rod 300 is advanced, the needle 310 of the valve rod 300 is advanced to a position adjacent to the nozzle 221 of the valve body 210. The viscous liquid L is discharged through the nozzle 221 when the valve rod 300 advances so that the needle 310 advances to the position adjacent to the nozzle 221 of the valve body 210. Discharge of the viscous liquid L stops when the valve rod 300 moves backward. The viscous liquid L stored in the nozzle 221 is discharged when the valve rod 300 moves forward again. This jetting pump method may discharge a minute amount of the viscous liquid L very accurately and quickly.

In the case of the spray pump of this embodiment, a shaking of a lower end of the valve rod 300 is suppressed through the reservoir guide 212 formed in the reservoir 211 and the valve guide 320 protruding from the valve rod 300 and inserted into the reservoir guide 212. Specifically, when the valve rod 300 is moved forward and backward by the operation member 400, the end portion of the valve rod 300 is prevented from shaking by an interaction between the valve guide 320 and the reservoir guide 212 and moves in a designated path. That is, the valve guide 320 is guided by the reservoir guide 212 while being inserted into the reservoir guide 212 to slide back and forth. Therefore, an opposite end portion (that is, a portion adjacent to the needle 310) of the valve rod 300 connected to the operation member 400 is not fixed with respect to other configurations, but quickly moves forward and backward in the designated path by the interaction of the reservoir guide 212 and the valve guide 320 without shaking. The reservoir guide 212 supports the valve guide 320 so that the valve guide 320 moves up and down without being shaken laterally.

As described above, the reservoir guide 212 is formed below the reservoir 211, and the valve guide 320 is also formed at the position corresponding to the reservoir guide 212. This point is a point where a lateral deformation of the valve rod 300 according to the shaking of the valve rod 300 may occur the most, but the reservoir guide 212 supports the valve guide 320 to slide without shaking in the lateral direction, so that no bending of the valve rod 300 occurs. In addition, it is preferable that a gap between the valve guide 320 and the reservoir guide 212 is formed as small as possible so that shaking due to vibration of the valve rod 300 may be minimized.

In addition, as described above, since the gap between the valve guide 320 and the reservoir guide 212 is small, it may be difficult to sufficiently supply the viscous liquid L to a space between the valve guide 320 and the reservoir guide 212 in some cases. In this case, the spray pump according to this embodiment includes a guide flow passage 213 so that the viscous liquid L is smoothly supplied to the nozzle 221 in the reservoir 211. The guide flow passage 213 is formed on the valve body 210 to connect the front space and the rear space of the reservoir guide 212. The viscous liquid L stored in the rear space of the reservoir guide 212 is moved along the guide flow passage 213 to the front space (i.e., the space adjacent to the nozzle 221) of the reservoir guide 212. Accordingly, the viscous liquid L may be smoothly supplied to the nozzle 221 in the reservoir 211 by the guide flow passage 213.

As described above, when the viscous liquid L is discharged from the nozzle 221 by a jetting way, a high-pressure gas for spraying the viscous liquid L is supplied to the sheath passage 231 from a pneumatic regulator (not illustrated) connected by the pipe. As described above, since the sheath passage 231 is inclined along a extending direction of the nozzle 221, the pressurized gas flowing into the sheath passage 231 is concentrated toward the nozzle 221 and is pressurized and discharged. That is, due to the shape of the sheath passage 231 in which the cross-section area gradually decreases along the extending direction of the nozzle 221, the gas supplied to the sheath passage 231 is injected at a faster speed as it approaches the nozzle 221. The gas of the sheath passage 231, whose pressure and speed have been increased in this way, collides with the viscous liquid L discharged from the nozzle 221 and effectively sprays the viscous liquid L. On the other hand, as the end of the sheath passage 231 is formed lower than the end of the nozzle 221, the pressurized gas injected into the sheath passage 231 guides the viscous liquid L sprayed from the nozzle 221 to be focused and sprayed downward at high density.

The gap between the nozzle cover member 230 and the nozzle member 220 may be adjusted by the fixing bolt 232. By adjusting the gap between the nozzle cover member 230 and the nozzle member 220, the flow rate of the gas injected from the sheath passage 231 may be adjusted, and the collision position and direction of the injected gas and the discharged viscous liquid L may be adjusted. Through this, spray characteristics of the viscous liquid L sprayed and discharged by the spray pump according to the present embodiment may be adjusted.

As described above, by using the spray pump according to the present disclosure, a highly viscous liquid L is also effectively sprayed, and the viscous liquid L may be coated at a correct position with an accurate quantity and a desired fine line width. Since a coating surface of the viscous liquid L is implemented with a certain thickness and precise line width, a high-quality electromagnetic wave shielding film process may be performed even for a small semiconductor chip or package.

In addition, the highly viscous liquid L discharged in the process of discharging the viscous liquid L collides with the high-pressure gas injected through the sheath passage 231 and is sprayed, so that a wide coating surface may be easily formed.

In addition, when the pressurized air is not discharged through the sheath passage 231, the viscous liquid L may be discharged in an unsprayed state. Therefore, the viscous liquid L may be applied by selecting whether to spray viscous liquid L as needed. Accordingly, with a single device, a relatively high capacity viscous liquid L may be applied in a predetermined pattern without spraying the viscous liquid L, or the viscous liquid L may be sprayed and applied to a small area with a low volume.

Although a preferable example has been described above for present disclosure, the scope of present disclosure is not limited to the form described and illustrated above.

For example, the operation member 400 has been described as using the piezoelectric actuators 410 and 420 composed of the piezoelectric element, but various devices that may linearly move the valve rod 300 may be used as the operation member. For example, a device such as a voice coil motor, a servo motor, or a pneumatic actuator may be applied.

In addition, it was previously described that the piezoelectric actuators 410 and 420 move the valve rod 300 forward and backward through the lever 440 rotatably installed on the hinge axis 430 in order to amplify a deformation amount of the piezoelectric actuators 410 and 420, but a connection relationship between the piezoelectric actuator and the valve rod may be changed in various ways.

In addition, the cross-sections of the reservoir guide 212 and the valve guide 320 have been described above as being formed in a cross shape (+), but the cross-sections of the reservoir guide and the valve guide may be variously changed. For example, the cross-section of the reservoir guide may be formed in a circular shape, and the cross-section of the valve guide may be formed in a circular shape corresponding to the reservoir guide. In addition, the cross-section of the reservoir guide may be formed in a non-circular shape like an ellipse, and the cross-section of the valve guide may be formed in a shape corresponding to the reservoir guide. The cross section of the reservoir guide may be formed in a polygonal shape, and the cross section of the valve guide may be formed in a polygonal shape corresponding to the reservoir guide. In addition to the structure described and illustrated above, the reservoir guide is formed in a shape extending in the reservoir, and the valve guide may be variously changed to have a shape in which movement may be restricted by the reservoir guide.

In addition, although it has been described above that the guide flow passage 213 is a passage formed separately in the valve body 210, a spray pump having a structure in which a part of the reservoir guide functions as the guide flow passage or the reservoir guide is not formed may be configured. For example, when the reservoir guide is configured in a cross shape as described above and the valve guide is configured in a shape similar to a flat screw driver, the viscous liquid L may flow through a groove into which the valve guide is not inserted. In addition, a spray pump of various structures in which the reservoir guide slides and supports the valve guide while allowing a flow path through which the viscous liquid L may flow between the reservoir guide and the valve guide may be configured.

In addition, a spray pump having a structure that does not include the reservoir guide 212, the valve guide 320, the guide flow passage 213, and the like may be configured.

On the other hand, it was previously described that the sheath passage 231 was connected between the inner surface of the nozzle cover member 230 and the outer surface of the nozzle member 220. However, a groove may be formed only on the inner surface of the nozzle cover member so that the sheath passage is formed between the nozzle cover member and the nozzle member, or a groove may be formed only on the outer surface of the nozzle member so that the sheath passage is formed between the nozzle cover member and the nozzle member. Also, the sheath passage may extend along the interior of the nozzle cover member so as to be formed only on the interior of the nozzle cover member. In some cases, a portion of the sheath passage may be formed in the nozzle member, and a remaining portion of the sheath passage may be formed in the nozzle cover member. That is, the beginning of the sheath passage may be formed in any one of the nozzle member and the nozzle cover member, and the end of the sheath passage may be formed in the other one of the nozzle member and the nozzle cover member.

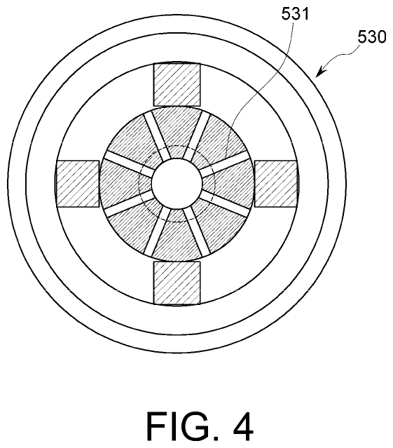

The sheath passage 231 of the above-described embodiment has been described as being formed in a ring shape inclined along the circumferential direction of the nozzle member 220, but the sheath passage may be formed in a radially extending structure as illustrated in FIG. 4. That is, the sheath passage may be formed of a plurality of straight sheath division passages 531 in a nozzle cover member 530. The plurality of straight sheath division passages 531 extend radially about the center of the nozzle 221 and arranged along the circumferential direction. The number, arrangement distance and shape of the sheath division passages 531 may be variously modified.

The spray pump of the present disclosure may micro-discharge the viscous liquid ranging from low to high viscosity in a quantitative manner.

The spray pump of the present disclosure may miniaturize devices capable of atomizing liquids by spraying.

The spray pump of the present disclosure may shorten a spraying path to prevent changes in liquid properties and keep spraying quality constant.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A spray pump comprising:
a syringe in which a viscous liquid is stored;
a valve member comprising
a reservoir receiving the viscous liquid from the syringe and storing the same,
a nozzle connected to a lower portion of the reservoir to discharge the viscous liquid to an outside, and
a sheath passage extending toward an end of the nozzle to discharge a gas to spray the viscous liquid discharged from the nozzle;
a valve rod inserted into the reservoir of the valve member so as to move forward and backward with respect to the nozzle of the valve member and discharge the viscous liquid stored in the reservoir through the nozzle; and
an operation member moving the valve rod back and forth with respect to the valve member.

2. The spray pump of claim 1, wherein the sheath passage of the valve member is formed such that an inner diameter decreases in a direction in which the nozzle extends.

3. The spray pump of claim 1, wherein the sheath passage of the valve member is formed to be closer to the nozzle as the sheath passage progresses in a direction in which the nozzle extends.

4. The spray pump of claim 1, wherein an end of the nozzle is disposed behind an end of the sheath passage.

5. The spray pump of claim 1, wherein the sheath passage comprises a plurality of sheath division passages arranged in a circumferential direction with respect to the nozzle.

6. The spray pump of claim 1, wherein the valve member comprises
a valve body on which the reservoir is formed,
a nozzle member on which the nozzle coupled to the valve body and extending from the valve body is formed, and
a nozzle cover member on which at least a portion of the sheath passage leading to the nozzle member is formed and which is coupled to the valve body.

7. The spray pump of claim 6, wherein the nozzle cover member is formed to cover a portion of the nozzle member.

8. The spray pump of claim 6, wherein the sheath passage of the valve member is formed in the nozzle cover member.

9. The spray pump of claim 6, wherein the sheath passage of the valve member is formed to be continuous between an inner surface of the nozzle cover member and an outer surface of the nozzle member.

10. The spray pump of claim 9, wherein an outer periphery of the nozzle member is formed to have an outer diameter that decreases in a direction in which the nozzle extends.

11. The spray pump of claim 9, wherein the nozzle cover member is coupled to the valve body so as to adjust a distance thereof to the nozzle member.

12. The spray pump of claim 11, wherein the nozzle cover member is screwed to the valve body, and a position thereof with respect to the valve body is fixed by a fixing bolt.

13. The spray pump of claim 1,
wherein the valve member further comprises a reservoir guide extending along a forward/backward direction of the valve rod in the reservoir of the valve member to guide a forward and backward movement of the valve rod, and
the valve rod comprises a valve guide formed in a shape corresponding to the reservoir guide so as to guide the forward and backward movement of the valve rod by being inserted into the reservoir guide and sliding forward and backward relative to the reservoir guide.

14. The spray pump of claim 13, wherein the reservoir guide is disposed on the lower portion of the reservoir.

15. The spray pump of claim 13, wherein the valve guide is formed to protrude with respect to an outer surface of the valve rod.

16. The spray pump of claim 13, wherein the reservoir guide is formed to have a cross section of any one of a non-circular shape and a polygonal shape.

17. The spray pump of claim 13, wherein the valve member further comprises a guide flow passage connecting a front space and a rear space of the reservoir guide in the reservoir so that the viscous liquid stored in the reservoir is smoothly supplied to the nozzle.
